(19) United States
(12) Patent Application Publication
(10) Pub. No.: US 2022/0208506 A1
(43) Pub. Date: Jun. 30, 2022

(54) ELECTRON BEAM EMITTING ASSEMBLY

(71) Applicant: AQUASIUM TECHNOLOGY LIMITED, Cambridge (GB)

(72) Inventor: Alex O'FARRELL, Cambridge (GB)

(21) Appl. No.: 17/605,886

(22) PCT Filed: Apr. 24, 2020
(86) PCT No.: PCT/GB2020/051011

§ 371 Date: Oct. 22, 2021

(30) Foreign Application Priority Data
Apr. 25, 2019 (GB) 1905758.7

(51) Int. Cl. H01J 37/06

(52) U.S. Cl. CPC H01J 37/06; H01J 37/315

(57) ABSTRACT

There is provided an electron beam emitting assembly (12) comprising a filament element (40; 60) and a cathode element (42; 62), wherein the filament element (40; 60) is in direct physical contact with the cathode element (42; 62). The filament element (40; 60) is heatable to a temperature around the electron emission temperature of the cathode element (42; 62). The filament element is resistively heatable or inductively heatable. Also provided is a method of generating an electron beam comprising positioning a filament element and a cathode element in direct physical contact, and heating the filament element to a temperature around the electron emission temperature of the cathode element so as to cause the cathode element to emit electrons.

### FIELD OF THE INVENTION

This invention relates to an electron beam emitting assembly, such as used in an electron beam gun used in electron beam welding.

### BACKGROUND TO THE INVENTION

Electron beam emitting assemblies are used within electron beam guns to position an emitter, cathode and anode relative to one another. The filament and cathode need replacing on a regular basis which is a complicated procedure requiring skilled personnel to modify the position and orientation of the emitter, cathode and anode relative to each other. Set-up procedures to ensure correct beam characteristics after replacing a filament take many hours.

### SUMMARY OF THE INVENTION

In accordance with one aspect of the present invention, there is provided an electron beam emitting assembly comprising a filament element and a cathode element, wherein the filament element is in direct physical contact with the cathode element. This allows the filament element to be used to directly heat the cathode element.

Preferably the filament element is heatable to a temperature around an electron emission temperature of the cathode element. Typically the filament element will be heated to just above the electron emission temperature of the cathode element, so as to ensure that the cathode element reaches its electron emission temperature. Typically the filament element will be heated to a temperature around 200 to 300° C. greater than the electron emission temperature of the cathode element.

The filament element may be resistively heatable or inductively heatable by connection to an electric supply.

The cathode element is preferably Lanthanum Hexaboride as this is particularly suitable for electron beam emission for welding purposes.

The filament element may be formed with a recess and the cathode element positioned to sit within the filament element, with at least one surface of the cathode element uncovered and free to emit electrons when the cathode element is at its electron emission temperature.

The assembly may further comprise a clamp, such as a Molybdenum clamp, to grip the filament element, particularly where the filament element needs to be inductively heatable. For such embodiments, a ceramic support may be used to hold the filament element in position within the clamp.

In accordance with another aspect of the invention there is provided a method of generating an electron beam comprising positioning a filament element and a cathode element in direct physical contact, and heating the filament element to a temperature around an electron emission temperature of the cathode element so as to cause the cathode element to emit electrons.

Typically the temperature to which the filament element is heated will be slightly above the electron emission temperature of the cathode element. The filament element will not be heated to its own electron emission temperature but will be substantially below its own electron emission temperature.

The method may further comprise resistively heating the filament element. Alternatively the method may comprise inductively heating the filament element.

The cathode element may be Lanthanum Hexaboride.

The method may further comprise disposing at least part of the filament element within a clamp, such as a Molybdenum clamp.

The method may further comprise disposing the cathode element within a recess formed in the filament element, at least one surface of the cathode element being uncovered and free to emit electrons.

The invention will now be described, by way of example, and with reference to the accompanying drawings in which:

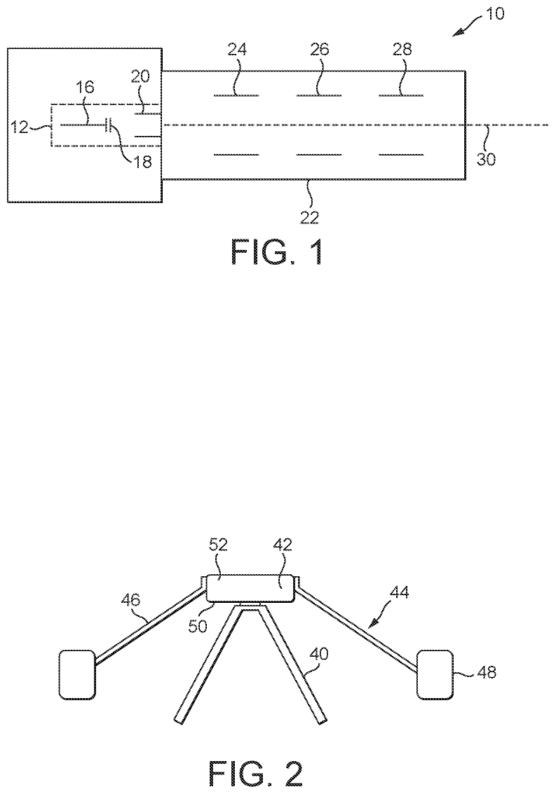

FIG. 1 is a schematic diagram of an electron beam gun incorporating an electron beam emitting assembly;

FIG. 2 is an end view of a first embodiment of a cathode and filament arrangement used in such an assembly;

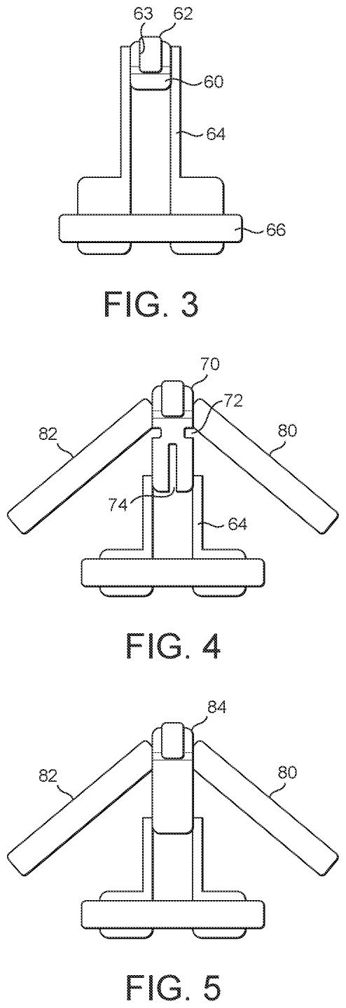

FIG. 3 is an end view of a second embodiment of a cathode and filament arrangement used in such an assembly;

FIG. 4 is an end view of a third embodiment of a cathode and filament arrangement used in such an assembly; and

FIG. 5 is an end view of a fourth embodiment of a cathode and filament arrangement used in such an assembly;

### DESCRIPTION

A schematic diagram of an electron beam gun 10 is shown in FIG. 1 for explanatory purposes. Electron beam assembly 12 from which electrons are generated is located in evacuatable housing 14, with assembly 12 comprising filament 16, cathode 18 and anode 20. Cathode 18 generates an electron beam which is accelerated through anode 20 to pass into a second evacuatable housing or chamber 22 in which are disposed focussing coils 24, alignment coils 26 and beam deflection coils 28 so as to produce a high energy focussed electron beam 30 for electron beam welding.

In prior art arrangements, filament 16 is spaced from cathode 18 and filament 16 is heated to its electron emission temperature to generate electrons which are accelerated towards cathode 18 to cause cathode 18 to generate an electron beam. The temperature to which filament 16 needs to be heated to emit electrons depends on the material from which the filament is made, with Tungsten filaments needing to be heated to 2600° C., Graphite filaments to 4000° C. and Tantalum/Molybdenum filaments to around 2400° C. Heating to such high temperatures causes the filaments to degrade and they need replacing often which involves time consuming realignment of the cathode, filament and other components in the electron beam gun.

In embodiments of invention and as shown in FIGS. 2 to 5, the filament is placed in direct contact with the cathode so as to directly heat the cathode to generate electrons. The filament does not need to be heated to its electron emission temperature but rather only to a temperature sufficient to ensure the cathode reaches its electron emission temperature. Thus for a Lanthanum Hexaboride cathode with an emission temperature of 1300° C., a Tungsten filament only needs to be heated to around 1500 to 1600° C. which is much lower than the temperature needed for electron emission from the filament.

By arranging direct contact between the cathode and the filament, the cathode can be stimulated to emit electrons without the filament needing to be heated to emission temperature.

By heating the filament to a lower temperature, the filament does not burn out so quickly. This ensures that the combination of filament and cathode lasts much longer than prior art arrangements, typically at least 10 times as long which is advantageous as it saves on delays in setting up with replacement filaments.

In the arrangement shown in FIG. 2, a Tungsten filament 40 directly contacts a Lanthanum Hexaboride LaB₆ cathode 42 in the form of a disc of around 4mm in diameter. Cathode 42 is mounted on a hollow frustoconical support 44 comprising a Tantalum cone 46 and a ceramic mounting ring 48. Filament 40 is connected to an electrical supply (not shown) and resistively heated to a temperature just above the emission temperature of cathode 42 and directly physically contacts a lower surface 50 of cathode 42 such that an electron beam is emitted from upper surface 52 of cathode 42.

In the arrangement shown in FIG. 3, La B₆ cathode 62 being a 1 mm diameter block is positioned within a recess 63 of a filament being a graphite cylinder 60, with a Molybdenum clamp 64 attaching to graphite cylinder 60. Electrical current is sent through Molybdenum clamp 64 to inductively heat graphite cylinder 60, with graphite cylinder 60 in direct physical contact with cathode 62 to heat cathode 62 to its electron emission temperature. Typically Molybdenum clamp 60 is secured within a ceramic holder 66.

In the arrangement shown in FIG. 3, a magnetic field is generated parallel to the extended arms of clamp 64. FIGS. 4 and 5 show alternative embodiments of the inductively heated filaments which have opposing current flow and ensure there is no magnetic field induced at the cathode. In FIG. 4, graphite filament 70 protrudes beyond clamp 64 and is formed with grooves 72, 74 so as to modify the magnetic field. Additional ceramic clamps 80, 82 are used to secure the top end of filament 70 which is distal from clamp 64. FIG. 5 shows a similar arrangement with ceramic clamps 82 but with filament 84 omitting any grooves.

If desired, the electron beam assembly can be supplied as a single item so that the filament and cathode are already positioned in direct physical contact with one another and do not need adjusting within the electron beam gun.

1. An electron beam emitting assembly comprising a filament element and a cathode element, wherein the filament element is in direct physical contact with the cathode element.

2. An electron beam emitting assembly according to claim 1, wherein the filament element is heatable to a temperature around an electron emission temperature of the cathode element.

3. An electron beam emitting assembly according to claim 1, wherein the filament element is resistively heatable.

4. An electron beam emitting assembly according to claim 1, wherein the filament element is inductively heatable.

5. An electron beam emitting assembly according to claim 1, wherein the cathode element is Lanthanum Hexaboride.

6. An electron beam emitting assembly according to claim 1, wherein the filament is formed with a recess and the cathode element is positioned to sit within the filament element.

7. An electron beam assembly according to claim 1, further comprising a clamp to grip the filament element.

8. A method of generating an electron beam comprising positioning a filament element and a cathode element in direct physical contact, and heating the filament element to a temperature around an electron emission temperature of the cathode element so as to cause the cathode element to emit electrons.

9. A method according to claim 8, wherein the temperature to which the filament element is heated is slightly greater than the electron emission temperature of the cathode element.

10. A method according to claim 8, further comprising resistively heating the filament element.

11. A method according to claim 8, further comprising inductively heating the filament element.

12. A method according to claim 8, wherein the cathode element is Lanthanum Hexaboride.

13. A method according to claim 8, further comprising disposing at least part of the filament element within a clamp.

14. A method according to claim 8, further comprising disposing the cathode element within a recess formed in the flame element.
